(19) United States
(12) Patent Application Publication
(10) Pub. No.: US 2024/0022221 A1
(43) Pub. Date: Jan. 18, 2024

(54) AMPLIFIER WITH BIAS CIRCUIT HAVING REPLICATED TRANSCONDUCTANCE DEVICES

(71) Applicant: QUALCOMM Incorporated, San Diego, CA (US)

(72) Inventors: Zaid ABOUSH, Chandler, AZ (US); Noshir Behli DUBASH, Phoenix, AZ (US); Abhijeet PAUL, San Diego, CA (US); Peter Graeme CLARKE, San Diego, CA (US)

(21) Appl. No.: 18/319,227

(22) Filed: May 17, 2023

Related U.S. Application Data
(60) Provisional application No. 63/368,616, filed on Jul. 15, 2022.

(51) Int. Cl. H03F 3/24; H03F 1/22; H03F 1/02

(52) U.S. Cl. CPC H03F 3/245; H03F 1/223; H03F 1/0277; H03F 2200/451; H03F 2200/294

(57) ABSTRACT

Devices and techniques for amplifying a signal are disclosed. For instance, an amplifier includes an input node and an output node; a first gain segment including: a first transistor, where a gate of the first transistor is coupled to the input node, a first terminal of the first transistor is coupled to a ground, and a second terminal of the first transistor is coupled to the output node; a second gain segment including: a second transistor, where a gate of the second transistor is coupled to the input node, a first terminal of the second transistor is coupled to the ground, and a second terminal of the second transistor is coupled to the output node, where the first gain segment and the second gain segment are arranged in parallel with respect to the output node; and a bias circuit.

### CROSS-REFERENCE TO RELATED APPLICATIONS

The present application claims the benefit of U.S. Provisional Application No. 63/368,616 filed Jul. 15, 2022, the disclosure of which is hereby incorporated herein by reference in its entirety.

### FIELD OF TECHNOLOGY

The technology discussed below relates generally to wireless communication circuitry, and, in particular, to an amplifier with a bias circuit having replicated transconductance (Gm) devices for use in radio receivers.

### BACKGROUND

A wireless device (e.g., smart phone) may transmit and receive radio frequency (RF) signals in one or more wireless networks (e.g., long-term evolution (LTE) network, fifth generation (5G) network, wireless local area network (WLAN), etc.). To receive RF signals, the wireless device includes one or more antennas and one or more low-noise amplifiers (LNAs) configured to amplify RF signals received by the one or more antennas.

### BRIEF SUMMARY OF SOME EXAMPLES

The following summarizes some aspects of the present disclosure to provide a basic understanding of the discussed technology. This summary is not an extensive overview of all contemplated features of the disclosure and is intended neither to identify key or critical elements of all aspects of the disclosure nor to delineate the scope of any or all aspects of the disclosure. Its sole purpose is to present some concepts of one or more aspects of the disclosure in summary form as a prelude to the more detailed description that is presented later.

In one aspect of the disclosure, an amplifier includes: a first gain segment including: a first transistor, wherein a gate of the first transistor is coupled to an input node of the amplifier, a first terminal of the first transistor is coupled to a power supply or ground, and a second terminal of the first transistor is coupled to an output node of the amplifier through a first cascode transistor; a second gain segment including: a second transistor, wherein a gate of the second transistor is coupled to the input node, a first terminal of the second transistor is coupled to the power supply or ground, and a second terminal of the second transistor is coupled to the output node through a second cascode transistor, wherein the first gain segment and the second gain segment are arranged in parallel with respect to the output node; a load impedance between the first transistor and a complementary power supply or ground and between the second transistor and the complementary power supply or ground; and a bias circuit including: a current source coupled to a first switchable transconductance (Gm) device and a second switchable Gm device, the first switchable Gm device and the second switchable Gm device being arranged in parallel with respect to a voltage bias node coupled to the current source, further wherein the voltage bias node is coupled to the gate of the first transistor and to the gate of the second transistor.

In another aspect of the disclosure, a method of operating an amplifier includes transitioning a first transconductance (Gm) device of a bias circuit from an off state to an on state, the first Gm device providing a first bias voltage to a second Gm device of a first amplifier segment; and transitioning the second Gm device from an off state to an on state synchronously with transitioning the first Gm device from the off state to the on state.

In another aspect of the disclosure, a method of operating a low noise amplifier (LNA) to amplify a radio frequency (RF) signal is disclosed, the method including: synchronizing turning on a first Gm device of a bias circuit with turning on a second Gm device of a first segment of the LNA, wherein the first Gm device provides a first bias voltage to the second Gm device; and synchronizing turning on a third Gm device of the bias circuit with turning on a fourth Gm device of a second segment of the LNA, wherein the third Gm device provides a second bias voltage to the fourth Gm device.

In yet another aspect of the disclosure, a low noise amplifier (LNA) includes: a radio frequency (RF) input; an RF output; a first gain segment including: a first transistor, wherein a gate of the first transistor is coupled to the RF input, a first terminal of the first transistor is coupled to a power supply or ground, and a second terminal of the first transistor is coupled to the RF output; a second gain segment including: a second transistor, wherein a gate of the second transistor is coupled to the RF input, a first terminal of the second transistor is coupled to the power supply or ground, and a second terminal of the second transistor is coupled to the RF output, wherein the first gain segment and the second gain segment are arranged in parallel with respect to the RF output; a bias circuit including: a current source coupled to a first transconductance (Gm) device and a second Gm device, the first Gm device and the second Gm device being arranged in parallel with respect to a voltage bias node coupled to the current source, further wherein the voltage bias node is coupled to the gate of the first transistor and to the gate of the second transistor; means for synchronizing a transition of the first transistor to an on state with a transition of the first Gm device to the on state; and means for synchronizing a transition of the second transistor to the on state a transition of the second Gm device to the on state.

### BRIEF DESCRIPTION OF THE DRAWINGS

The accompanying figures, where like reference numerals refer to identical or functionally similar elements throughout the separate views and which together with the detailed description below are incorporated in and form part of the specification, serve to further illustrate various implementations and to explain various principles and advantages in accordance with the present disclosure.

FIG. 1 illustrates a diagram depicting a wireless communication system, in accordance with aspects of the present disclosure.

FIG. 2 illustrates a block diagram depicting an example wireless device, in accordance with aspects of the present disclosure.

FIG. 3 illustrates an example amplifier, in accordance with aspects of the present disclosure.

FIG. 4 illustrates an example bias circuit, for use with an amplifier, in accordance with aspects of the present disclosure.

FIG. 5 illustrates an example bias circuit, for use with an amplifier, in accordance with aspects of the present disclosure.

FIG. 6 illustrates an example bias circuit, for use with an amplifier, in accordance with aspects of the present disclosure.

FIG. 7 illustrates an example amplifier, in accordance with aspects of the present disclosure.

FIG. 8 is a flow chart depicting an example operation for operating an amplifier, in accordance with aspects of the present disclosure.

### DETAILED DESCRIPTION

The detailed description set forth below in connection with the appended drawings is intended as a description of various configurations and is not intended to represent the only configurations in which the concepts described herein may be practiced. The detailed description includes specific details for the purpose of providing a thorough understanding of various concepts. However, it will be apparent to those skilled in the art that these concepts may be practiced without these specific details. In some instances, well known structures and components are shown in block diagram form in order to avoid obscuring such concepts.

Silicon on insulator (SOI) devices may sometimes experience the floating body issue, which is due to charge collection in the body due to impact ionization from the drain side of the device. It takes a finite amount of time to remove the body charge, and this amount of time may be referred to as “device body [resistive capacitive] RC delay.” The body charge starts to move out of the source side as the body source diode becomes more forward biased. The delay in the charge removal from the body in SOI may lead to unknown potential for a finite amount of time, e.g., from milliseconds to micro-seconds.

The change in body voltage may cause a shift in metal oxide semiconductor field effect transistor (MOSFET) threshold voltage (Vth). The shift in threshold voltage may in turn change the MOSFET overdrive capability. In a scenario in which a SOI device is used in a bias circuit or in an amplifier receiving a bias voltage, the change in overdrive capability may cause the bias voltage to change accordingly. Bias voltage change may cause the bias current and gain to change. Depending on the SOI device structure, the settling time of the body voltage (hence, bias current and gain) can be significant and in the order of few milliseconds.

In one example, a low noise amplifier (LNA) transconductance (Gm) device is an SOI device, and a bias circuit, used to bias that LNA Gm device, is also an SOI device. When either the LNA Gm device or the bias circuit device transitions from an off state to an on state, such device may experience the floating body effect for the finite amount of time. This may cause a threshold voltage mismatch between the LNA Gm device and the bias device, which may cause an overshoot or undershoot of gain that takes an undesirable amount of time to settle.

Various embodiments use SOI devices for both bias circuits and amplifiers, using synchronous operation (e.g., switching) to reduce an amount of gain settling experienced by an amplifier. For instance, the transistors used in a bias circuit may be replicas of the transistors used in their corresponding amplifiers. In some examples, a replica may refer to a device that has a same length and either a same width or a different width as another device on a same wafer. For instance, a bias circuit may use a Gm device to produce a bias voltage, the bias voltage being applied to a gate of a Gm device of an amplifier. The Gm device of the bias circuit may be a replica of the Gm device of the amplifier so that the direct current (DC) current through the bias circuit current mirrors is proportional to the DC current through the Gm device of the amplifier. A voltage associated with the Gm device of the bias circuit may be applied to a gate of the Gm device of the amplifier, thereby providing a bias voltage to the amplifier.

Continuing with the example, synchronous switching may be used at the bias circuit and the amplifier so that the Gm device of the bias circuit and its corresponding Gm device of the amplifier transition from an off state to an on state at substantially the same time. As a result of transitioning from an off state to an on state, both of the Gm devices may experience threshold voltage reduction that settles over time. However, since the Gm device at the bias circuit replicates the Gm device of the amplifier, both of the Gm devices experience a similar threshold voltage reduction at the same time and a similar threshold voltage settling time. Thus, the transient event affecting the bias voltage is counteracted by the transient event affecting the threshold voltage of the Gm device of the amplifier, and gain may be expected to stay within an acceptable range even during and after the settling time of the body voltages of the Gm devices.

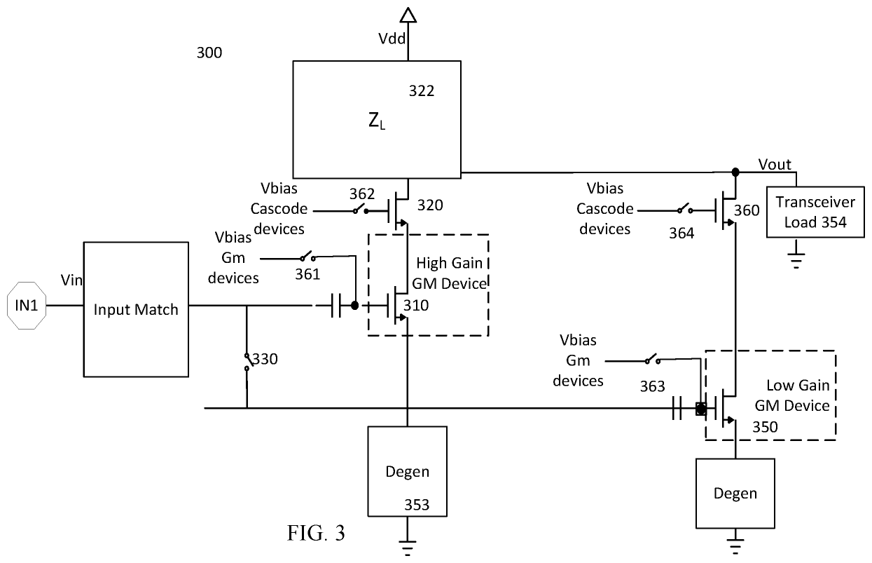

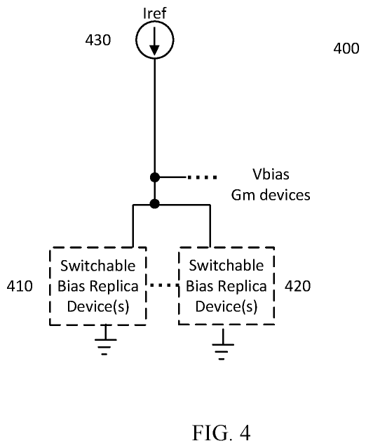

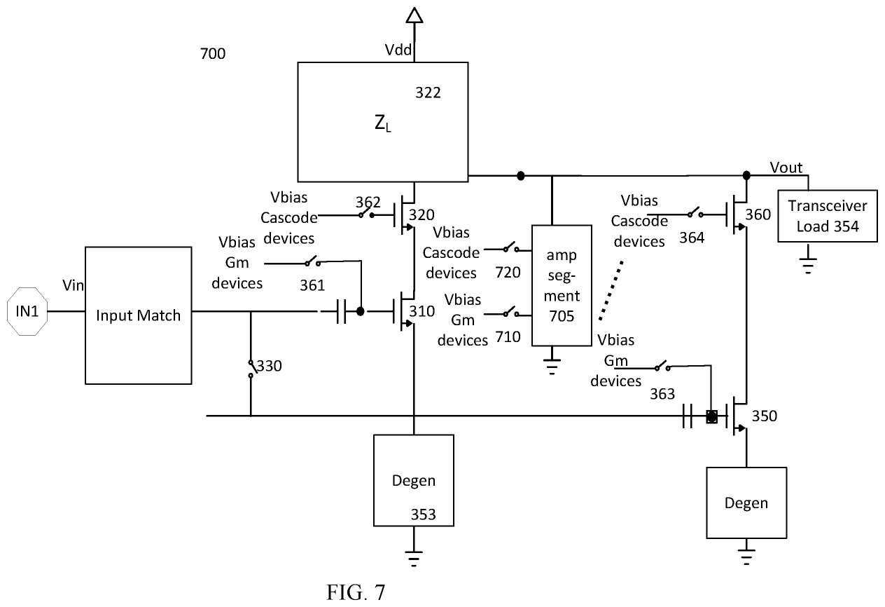

Various implementations may be used with different architectures for both bias circuits and amplifiers. For instance, FIGS. 3 and 7 provide examples of amplifiers, and FIGS. 4-6 provide examples of bias circuits, though the scope of implementations may include any appropriate bias circuit or amplifier. Furthermore, various implementations may find use in communication devices, such as within amplifiers for radiofrequency (RF) communication.

Communication devices may transmit and receive communication data through a communication medium. The electromagnetic spectrum is often subdivided, based on frequency/wavelength, into various classes, bands, channels, etc. In one example, the communication medium may be a wireless communication medium where communication data is transmitted and received by communication devices according to a wireless communication protocol.

Example wireless communication protocols may include the IEEE 802.11 protocols (e.g., Wi-Fi), Bluetooth protocols according to the Bluetooth Special Interest Group, Long Term Evolution (LTE), and a fifth generation (5G) wireless communications technology (also referred to as 5G new radio (5G NR)). Wi-Fi communications may operate in either a frequency band centered around 2.4 GHz (e.g., 2.4G Wi-Fi communications) or a frequency band centered around 5 GHz (e.g., 5G Wi-Fi communications). LTE is a set of enhancements to the Universal Mobile Telecommunications System (UMTS) mobile standard promulgated by Third Generation Partnership Project (3GPP). LTE communications may operate in portions of the licensed frequency spectrum (e.g., between approximately 700 MHz-2.6 GHz; may be known as LTE-L) and may operate in portions of the unlicensed frequency spectrum (e.g., around 5 GHz; may be known as LTE-U). In 5G NR two initial operating bands have been identified as frequency range designations FR1 (410 MHz-7.125 GHz) and FR2 (24.25 GHz-52.6 GHz). It should be understood that although a portion of FR1 is greater than 6 GHz, FR1 is often referred to (interchangeably) as a “Sub-6 GHz” band in various documents and articles. A similar nomenclature issue sometimes occurs with regard to FR2, which is often referred to (interchangeably) as a “millimeter wave” band in documents and articles, despite being different from the extremely high frequency (EHF) band (30 GHz-300 GHz) which is identified by the International Telecommunications Union (ITU) as a “millimeter wave” band. The frequencies between FR1 and FR2 are often referred to as mid-band (MB) frequencies. Recent 5G NR studies have identified an operating band for these mid-band frequencies as frequency range designation FR3 (7.125 GHz-24.25 GHz). Frequency bands falling within FR3 may inherit FR1 characteristics and/or FR2 characteristics, and thus may effectively extend features of FR1 and/or FR2 into mid-band frequencies. In addition, higher frequency bands are currently being explored to extend 5G NR operation beyond 52.6 GHz. For example, three higher operating bands have been identified as frequency range designations FR4-a or FR4-1 (52.6 GHz-71 GHz), FR4 (52.6 GHz-114.25 GHz), and FR5 (114.25 GHz-300 GHz). Each of these higher frequency bands falls within the EHF band.

While aspects and examples are described in this application by illustration to some examples, those skilled in the art will understand that additional implementations and use cases may come about in many different arrangements and scenarios. Innovations described herein may be implemented across many differing platform types, devices, systems, shapes, sizes, and packaging arrangements. For example, aspects and/or uses may come about via integrated chip examples and other non-module-component-based devices (e.g., end-user devices, vehicles, communication devices, computing devices, industrial equipment, retail/purchasing devices, medical devices, AI-enabled devices, etc.). While some examples may or may not be specifically directed to use cases or applications, a wide assortment of applicability of described innovations may occur. Implementations may range in spectrum from chip-level or modular components to non-modular, non-chip-level implementations and further to aggregate, distributed, or original equipment manufacturer (OEM) devices or systems incorporating one or more aspects of the described innovations. In some practical settings, devices incorporating described aspects and features may also necessarily include additional components and features for implementation and practice of claimed and described examples. For example, transmission and reception of wireless signals necessarily includes a number of components for analog and digital purposes (e.g., hardware components including antenna, RF-chains, power amplifiers, modulators, buffer, processor(s), interleaver, adders/summers, etc.). It is intended that innovations described herein may be practiced in a wide variety of devices, chip-level components, systems, distributed arrangements, end-user devices, etc., of varying sizes, shapes, and constitution.

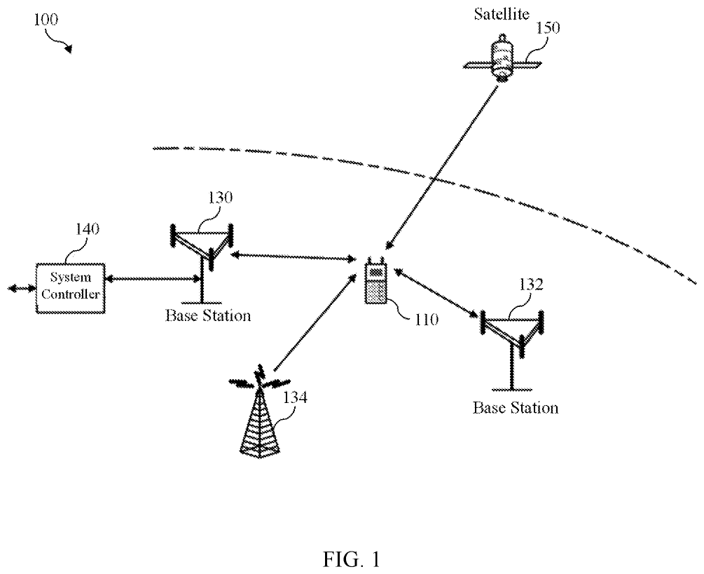

The various concepts presented throughout this disclosure may be implemented across a broad variety of telecommunication systems, network architectures, and communication standards. Referring now to FIG. 1, as an illustrative example without limitation, various aspects of the present disclosure are illustrated with reference to a wireless communication system 100. The wireless communication system 100 includes a wireless device 110 communicating with a wireless network.

The wireless communication system 100 may implement any suitable wireless communication technology or technologies to provide radio access to the wireless device 110. As one example, the wireless communication system 100 may operate according to 3rd Generation Partnership Project (3GPP) New Radio (NR) specifications, often referred to as 5G. As another example, the RAN may operate under a hybrid of 5G NR and Evolved Universal Terrestrial Radio Access Network (eUTRAN) standards, often referred to as Long Term Evolution (LTE). Of course, many other examples may be utilized within the scope of the present disclosure. For example, the wireless communication system 100 may be a 5G NR system, an LTE system, a Code Division Multiple Access (CDMA) system, a Global System for Mobile Communications (GSM) system, a wireless local area network (WLAN) system (e.g., a Wi-Fi system), or any other suitable wireless system. A CDMA system may implement Wideband CDMA (WCDMA), CDMA 1×, Evolution-Data Optimized (EVDO), Time Division Synchronous CDMA (TD-SCDMA), or some other version of CDMA. For simplicity, FIG. 1 shows the wireless communication system 100 including two base stations 130 and 132 and one system controller 140. In general, a wireless system may include any number of base stations and any set of network entities.

The wireless device 110 may also be referred to as a user equipment (UE), a mobile station, a terminal, an access terminal, a subscriber unit, a station, etc. Wireless device 110 may be a cellular phone, a smartphone, a tablet, a wireless modem, a personal digital assistant (PDA), a handheld device, a laptop computer, a smartbook, a netbook, a cordless phone, a wireless local loop (WLL) station, a Bluetooth device, etc. The wireless device 110 may also receive signals from broadcast stations (e.g., a broadcast station 134), signals from satellites (e.g., a satellite 150) in one or more global navigation satellite systems (GNSS), etc. The wireless device 110 may support one or more radio technologies for wireless communication such as 5G NR, LTE, WCDMA, CDMA 1×, EVDO, TD-SCDMA, GSM, 802.11, etc.

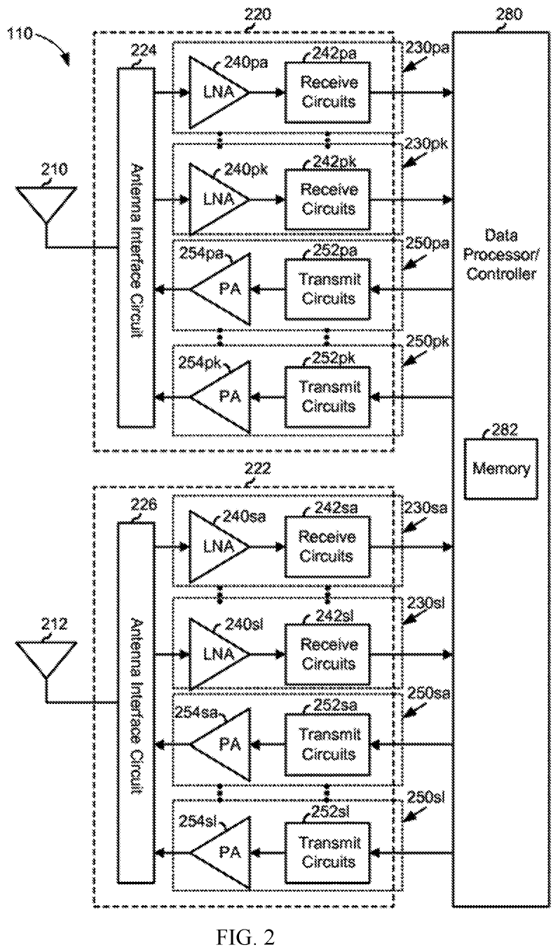

FIG. 2 is a block diagram depicting an example wireless device 110, in accordance with some implementations. For the example of FIG. 2, the wireless device 110 is shown to include a primary transceiver 220 coupled to a primary antenna 210, a secondary transceiver 222 coupled to a secondary antenna 212, and a data processor/controller 280. The primary transceiver 220 includes a number (K) of receivers 230pa to 230pk and a number (K) of transmitters 250pa to 250pk to support multiple frequency bands, multiple radio technologies, carrier aggregation, transmit diversity, and/or multiple-input multiple-output (MIMO) communications. The secondary transceiver 222 includes a number (L) of receivers 230sa to 230s1 and a number (L) of transmitters 250sa to 250s1 to support multiple frequency bands, multiple radio technologies, carrier aggregation, receive diversity, and/or MIMO communications.

For the example of FIG. 2, each receiver 230 (e.g., 230pa-230pk and 230sa-230sl) includes at least a low noise amplifier (LNA) 240 (e.g., 240pa-240pk and 240sa-240sl) and a receive circuit 242 (e.g., 242pa-242pk and 242sa-242sl). For data reception, the primary antenna 210 receives signals from base stations and/or other transmitter stations and provides a received radio frequency (RF) signal, which is routed through a primary antenna interface circuit 224 and presented as an input RF signal to a selected receiver. Primary antenna interface circuit 224 may include switches, duplexers, transmit filters, receive filters, matching circuits, and other suitable components or circuits. The description below assumes that the receiver 230pa is the selected receiver for ease of illustration. Within the receiver 230pa, an LNA 240pa amplifies the input RF signal and provides an output RF signal. The receive circuit 242pa may down-convert the output RF signal from RF to baseband, amplify and filter the down-converted signal, and provide an analog input signal to data processor/controller 280. The receive circuits 242pa may include mixers, filters, amplifiers, an oscillator, a local oscillator (LO) generator, a phase locked loop (PLL), and other suitable components or circuits. Each remaining receiver 230pa to 230pk and 230sa to 230s1 in the transceivers 220 and 222 may operate in similar manner as the receiver 230pa.

For the example of FIG. 2, each transmitter 250 (e.g., 250pa-250pk and 250sa-250sl) includes at least a transmit circuit 252 (e.g., 252pa-252pk and 252sa-252s1) and a power amplifier (PA) 254 (e.g., 254pa-254pk and 254sa-254sl). For data transmission, the data processor/controller 280 processes (e.g., encodes and modulates) data to be transmitted and provides an analog output signal to a selected transmitter. The description below assumes that transmitter 250pa is the selected transmitter for ease of illustration. Within the transmitter 250pa, the transmit circuit 252pa may amplify, filter, and up-convert the analog output signal from baseband to RF and provide a modulated RF signal. The transmit circuit 252pa may include amplifiers, filters, mixers, matching circuits, an oscillator, an LO generator, a PLL, and other suitable components or circuits. A PA 254pa receives and amplifies the modulated RF signal and provides a transmit RF signal having the proper output power level. The transmit RF signal is routed through antenna interface circuit 224 and transmitted via primary antenna 210. Each remaining transmitter 250 in the transceivers 220 and 222 may operate in similar manner as the transmitter 250pa. In a similar manner, secondary antenna interface circuit 226 may route RF signals between secondary antenna 212 and secondary LNA module 240s and/or secondary power amplifier module 254s.

Each receiver 230 and transmitter 250 may also include other circuits not shown in FIG. 2, such as filters, matching circuits, and/or other suitable components or circuits. All or a portion of the transceivers 220 and 222 may be implemented on one or more analog integrated circuits (ICs), RF ICs (RFICs), mixed-signal ICs, and other suitable ICs. For example, the LNAs 240 and the receive circuits 242 within the transceivers 220 and 222 may be implemented on multiple IC chips. The circuits in the transceivers 220 and 222 may also be implemented in other manners.

The data processor/controller 280 may perform various functions for the wireless device 110. For example, the data processor/controller 280 may perform processing for data being received via the receivers 230 and data being transmitted via the transmitters 250. The data processor/controller 280 may control the operations of the various circuits within the transceivers 220 and 222. For instance, the embodiments herein described synchronized switching functions that may happen within an LNA (e.g., any of the LNAs 240), and the synchronized switching functions in some examples may be accomplished by the data processor/controller 280 providing appropriate control signals to open or close switches and/or control operation of transistors. A memory 282 may store program codes and data for the data processor/controller 280, which the data processor/controller 280 may execute to provide described functionality. The data processor/controller 280 may be implemented on one or more application specific integrated circuits (ASICs) and/or other ICs.

FIG. 3 illustrates an example low noise amplifier (LNA) 300 according to one implementation. The architecture and switching techniques associated with LNA 300 may be adapted into the amplifiers (e.g., LNAs 240 or other amplifiers) within the receive chain of wireless device 110 of FIG. 2.

The LNA 300 includes two amplification stages (also referred to as an amplification segment), a first of which includes an input transistor 310 coupled to a cascode transistor 320. In this implementation, the cascode transistor 320 is connected to Vdd via load impedance 322 (e.g., may include one or more inductors and other conditioning circuitry), e.g., tunable LC or RC circuit. The output signal Vout of the amplification stage is provided to the transceiver load 354. The load impedance 322 in other implementations may include one or more inductors or a transformer (or transformer implemented as a balun for providing a double ended (or differential) output voltage. An input signal Vin to the LNA 300, e.g., as derived from an output of the antenna 210 of FIG. 2, is coupled to the gate of the input transistor 310.

The second amplification stage (or amplification segment) includes input transistor 350 in series with cascode transistor 360. The drain of the cascode transistor 360 supports the single ended output voltage of this amplification stage via the load impedance 322. The input signal Vin may be applied to the gate of the input transistor 350. In some examples, the two amplification stages may be used at different times to provide a desired level of gain. In this example, the amplification stage including transistors 310 and 320 may provide a high or low gain, and the amplification stage including transistors 350, 360 may provide an extra low gain (e.g., or at least a gain that is lower than a gain provided by the amplification stage including transistors 310 and 320). However, the scope of implementations is not limited to any level of gain nor to any particular number of gain stages, as it is understood that the example of FIG. 3 may be scaled to include more or fewer amplification stages and different selection of gain levels.

In this particular example, the transistors 310, 350 act as transconductance (Gm) devices, and the transistors 320, 360 are implemented as cascodes. Thus, the LNA 300 in this example is implemented as a cascode amplifier having at least two levels: a first level with a transconductance part and a second level with a load part. For a two-level cascode amplifier, the first level includes input amplification circuitry provided by transistors 310, 350, and the second level includes cascode amplification circuitry provided by transistors 320, 360. Thus, the cascode amplification circuitry provides an amplified signal at the output via the load impedance 322. Degeneration device 353 is provided between transistor 310 and ground.

A transceiver load 354 (e.g., further receive processing circuitry such as receive circuit 242pa of FIG. 2) is coupled between a supply voltage (VDD) and the cascode amplification circuitry 320, 360 of each of the amplification stages. For a particular amplification stage, the amplified signal is generated based on a current through its respective cascode 320, 360 and flowing from VDD to ground through the respective amplification circuitry 310, 350. Transceiver load 354 represents a downstream component, such as a filter, a mixer, or a converter unit.

In this example, the LNA 300 is implemented with a higher gain path to the first amplification stage (e.g., transistor 310) and a lower gain path to the second amplification stage (e.g., transistor 350). The lower gain path allows the input signal Vin to bypass the higher gain path to arrive at the output of the LNA 300. The lower gain path includes a switching circuitry 330. The lower gain path may also be referred to as a bypass path. When transistors 310, 320 are in an off state, the switching circuitry 330 is closed to route the input signal Vin through the lower gain path instead of the high gain path. Through the lower gain path, the input signal Vin is routed to the output of the LNA 300 with an amplification level consistent with that provided by transistors 350, 360.

The operation of LNA 300 will now be described with further reference to FIG. 4, which illustrates an example bias circuit 400 for use with various LNAs, including LNA 300. Bias circuit 400 includes a current source 430, which provides the current Iref to either one of the switchable bias replica devices 410, 420 at a given time. In one example, the switchable bias replica devices 410, 420 include at least one switch as well as at least one Gm device that is a replica of transistor 310. In this example, a replica device refers to a device that is manufactured using same or similar processes on a common wafer (e.g., and potentially having a same length and a same or different width as the device which it replicates). For instance, the Gm device of switchable bias replica device 410 may include a transistor having a same length as transistor 310 but having a smaller number of fingers than transistor 310, thereby experiencing a bias current from current source 430 to ground through switchable bias replica device 410. Another example uses a bias device that has a different length than the LNA GM device. In any event, mirrored current will eventually be set by the width/length (W/L) ratio of the devices. The bias current through switchable bias replica device 410 may be smaller yet proportional to the current that flows through transistors 310, 320.

The concept of being a replica applies to the switchable bias replica device 420 as well. In this example, the switchable bias replica device 420 is a replica of transistor 350, and it also provides a bias current that is smaller yet proportional to the current through transistors 350, 360. Further in this example, the switchable nature of each of the devices 410, 420 is used so that either one of the devices 410, 420 may be in an on state at a given time, though it is unlikely that both would be in an on state (or an off state) at a given time during normal operation. In other words, at any given time current would flow either through switchable bias replica device 410 or switchable bias replica device 420. Although not shown explicitly in FIG. 4, the switches of switchable bias replica devices 410, 420 may be controlled by data processor/controller 280 of FIG. 2 or other appropriate logic.

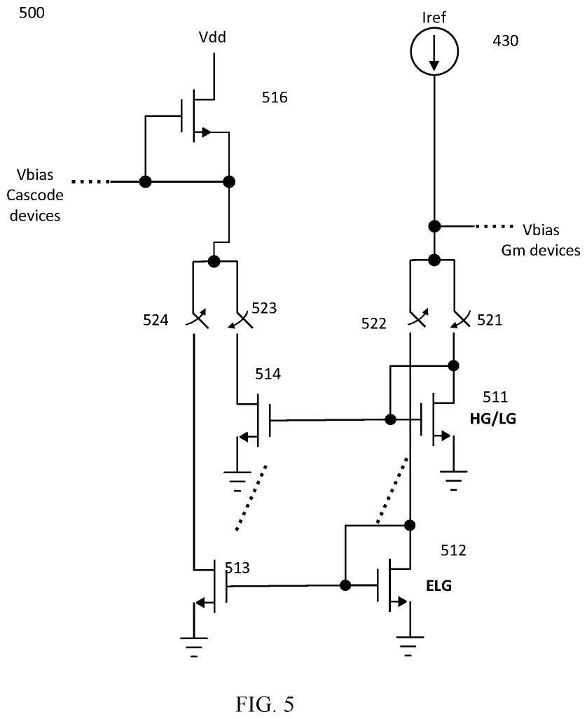

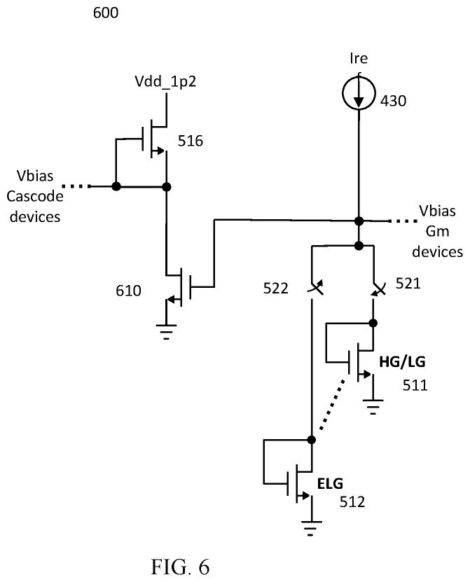

Bias circuit 400 provides a bias voltage (Vbias Gm devices), which is a direct current (DC) voltage that may be applied to the respective gates of transistors 310, 350, as shown in FIG. 3. For instance, when switchable bias replica device 410 is on, bias circuit 400 may provide the bias voltage to the gate of transistor 310 through switch 361. Similarly, when switchable bias replica device 420 is on, bias circuit 400 may provide the bias voltage to the gate of transistor 350 through switch 363. In other words, when the higher gain path is used, switches 361, 362 may be closed, and switches 363, 364 may be opened; when the lower gain path is used, switches 361, 362 may be opened, and switches 363, 364 may be closed. The switches 361-364 may be controlled by data processor/controller 280 of FIG. 2 or other appropriate logic. Although not shown explicitly in FIG. 4, some implementations may include further switches and Gm devices in 410 and 420 to provide a bias voltage (e.g., Vbias cascode devices) to cascodes 320, 360. Examples of cascode bias voltage generation are shown in FIGS. 5 and 6.

In one example, the transistors 310, 350 as well as their replicas in respective switchable bias replica devices 410, 420 are silicon on insulator (SOI) devices, which may experience the floating body effect. The floating body effect may be experienced when a transistor transitions from an off state to an on state, and there may be some delay from when the on state begins until when the extra charge in the body is discharged through the source of its transistor. The floating body effect may be noticeable with respect to a given transistor by a temporary drop in threshold voltage, with the threshold voltage returning to its desired level when the extra charge of the body is discharged through the source.

The architecture of FIGS. 3-4 may be operated to ameliorate the effects of the floating body effect by synchronized switching of the devices 410, 420 with their respective transistors 310, 350. For instance, when the higher gain path is in use, the transition from the off state to the on state of transistor 310 may be synchronized to coincide with the transition from the off state to the on state of switchable bias replica device 410. Therefore, a reduction in threshold voltage of transistor 310 coincides in time with a reduction in threshold voltage of the Gm device of the switchable bias replica device 410, and it is expected that the threshold voltage of both transistor 310 and the Gm device of the switchable bias replica device 410 return to their normal levels within a similar timeframe as well. The reduction in threshold voltage of the Gm device of the switchable bias replica device 410 may reduce the level of the Vbias Gm devices signal by a proportional amount, which keeps the gain of the transistors 310, 320 from overshooting. In fact, in some implementations, the reduction in Vbias Gm devices as transistor 310 experiences the floating body effect may operate to keep the gain of transistors 310, 320 within an acceptable range for some applications.

Operation of the lower gain path is similar to that described above with respect to the higher gain path. In other words, the transistor 350 and the Gm device of the switchable bias replica device 420 may transition from the off state to the on state coinciding in time so that the gain experienced by transistors 350, 360 is within an acceptable range for some applications. In some aspects, the switchable bias replica device 420 is transitioned to the on state at the same time the transistor 350 of the Gm device is transitioned to the on state in response to a transition from the higher gain path to the lower gain path (e.g., the synchronization of the switching of the bias replica device and activation of gm devices are done in response to switching between the different gains paths in response to a switch in gain mode operation).

The scope of implementations is not limited to two switchable bias replica devices 410, 420 as the bias device 400 may be scaled to serve any appropriate number of amplification stages in the LNA 300. FIGS. 5-6 show a variety of example implementations for the bias device 400, according to various embodiments.

Looking at or into FIG. 5 first, it shows an example bias circuit 500, for use with an amplifier, such as LNA 300, and FIG. 5 illustrates an architecture to which bias circuit 400 may be adapted.

Bias circuit 500 includes transistors 511-516. Transistors 511, 512 are used to provide Vbias Gm devices, and transistors 513-516 are used to provide Vbias cascode devices. Transistor 511 is a diode-connected transistor, and it is a replica of transistor 310, and transistor 512 is a diode connected transistor, and it is a replica of transistor 350.

During operation of the higher gain path of the LNA 300, switches 521 and 523 are closed, and switches 522, 524 are opened. Similarly, (at FIG. 3) switches 361, 362 are closed, and switches 363, 364 are opened. The switches 521 and 523 are synchronized with switches 361, 362 so that they open at substantially the same time and close at substantially the same time (and in some scenarios the switches 521 and 523 may be controlled by the same control signals as the switches 361 and 362). As a result, transistor 310 and transistor 511 transition from the off state to the on state and experience the floating body effect at the same time. As explained above, this is expected to keep the gain of transistor 310, 320 from overshooting and staying within an acceptable range.

During operation of the lower gain path of the LNA 300, switches 522, 524 are closed, and switches 521, 522 are opened. Similarly, (at FIG. 3) switches 363, 364 are closed, and switches 361, 362 are opened. The switches 522, 524 are synchronized with switches 363, 364 so that they open at substantially the same time and close at substantially the same time. As a result, transistor 350 as well as transistor 512 experience the floating body effect at the same time. In some scenarios the switches 522 and 524 may be controlled by the same control signals as the switches 363 and 364. explained above, this is expected to keep the gain of transistor 350, 360 from overshooting and staying within an acceptable range.

Once again, the scope of implementations may include any number of Gm devices and switches within the bias circuit 500 to accommodate any appropriate number of amplification stages at the LNA. Also, the switches 521-524 may be controlled by the data processor/controller 280 or other appropriate logic.

FIG. 6 illustrates an example bias circuit 600, for use with an amplifier, such as LNA 300, and FIG. 6 illustrates an architecture to which bias circuit 400 may be adapted.

Compared to the embodiment of FIG. 5, the embodiment of FIG. 6 omits the switches 523, 524 and the transistors 513, 514; instead, using transistor 610. Transistors 516, 610 are used to provide the Vbias cascode devices signal. As described above, switch 521 is synchronized with switches 361 and 362, and switch 522 is synchronized with switches 363 and 364. The embodiment of FIG. 6 may reduce an amount of semiconductor area used. In some scenarios the switches 521 and 523 may be controlled by the same control signals as the switches 361 and 362. As with the embodiment of FIG. 5, the embodiment of FIG. 6 may be scaled to accommodate any appropriate number of amplification stages of the LNA and may be controlled by the data processor/controller 280 or other appropriate logic.

FIG. 7 illustrates an example LNA 700, for use with a bias circuit, such as those described above with respect to FIGS. 4-6. FIG. 7 illustrates an architecture to which LNA 300 may be adapted.

FIG. 7 is offered to illustrate that the LNA architecture may be scaled to include any number of gain segments as appropriate. For instance, LNA 700 includes gain segment 705, which may be adapted for use as a high gain (HG) segment, a low gain (LG) segment, an extra low gain (ELG) segment, or any other appropriate gain level. Furthermore, gain segment 705 may be switched together with the gain segment that includes devices 310, 320, with the gain segment that includes devices 350, 360, with other gain segments (not shown), or by its self.

Gain segment 705 may be implemented similarly to the other bias segments; that is, gain segment 705 may include a cascode and an amplifier transistor. Furthermore, a dotted line is shown to indicate that gain segment 705 may be one of multiple bias segments in addition to the bias segments that were shown in FIG. 3.

Gain segment 705 includes switches 710, 720, which may be switched synchronously with corresponding switches of a bias circuit, such as those bias circuits shown in FIGS. 4-6. As the transistors of gain segment 705 transition from the off state to the on state, the switches 710, 720 are synchronized with switches in the bias circuit so that corresponding Gm devices in the bias circuit turn on and experience the floating body effect at substantially the same time. For instance, in FIG. 5, switches 521, 523 may be closed, while switches 522, 524 are open, and the opening and closing of the switches 521, 523 may be coordinated with the switches 710, 720. Of course, that assumes that gain segment 705 is switched along with the gain segment that includes devices 310, 320. Alternatively, gain segment 705 may be biased so that switches 521, 523 may be opened, while switches 522, 524 are closed, and the opening and closing of the switches 522, 524 may be coordinated with the switches 710, 720. In other words, gain segment 705 may be switched along with the gain segment that includes devices 350, 360. Alternatively, gain segment 705 may be switched independently of either of those gain segments and may be synchronized with other parallel biasing legs (not shown) of the bias circuits 400, 500, 600. Once again, the bias circuit 400, 500, 600 may be scaled to bias any appropriate number of gain segments. Also, the principle of threshold voltage tracking can be applied to an LNA with multiple cores to support different RF inputs, and these core GM devices can be segmented and share the same or different cascode devices and the same load.

Any of the transistors 310, 320, 350, 360 may be implemented as n-channel MOSFET (NMOS) or p-channel MOSFET (PMOS) devices as appropriate. When turning an NMOS device (e.g., 320) off, the series bias switch (e.g., 362) may be opened, and additionally the device gate may be pulled to ground by another switch (not shown) to make sure the NMOS device is completely off.

Furthermore, each of the different amplifier segments may have the same or different gain. The sizes of the transistors 310, 320, 350, 360 (and any of the transistors in amplification segment 705) may be sized as appropriate for a given gain. Also, when using the segment that includes transistors 350, 360 as a lower gain path, the path may include one or more attenuators (not shown) between switch 330 and transistor 350 to provide a difference in gain.

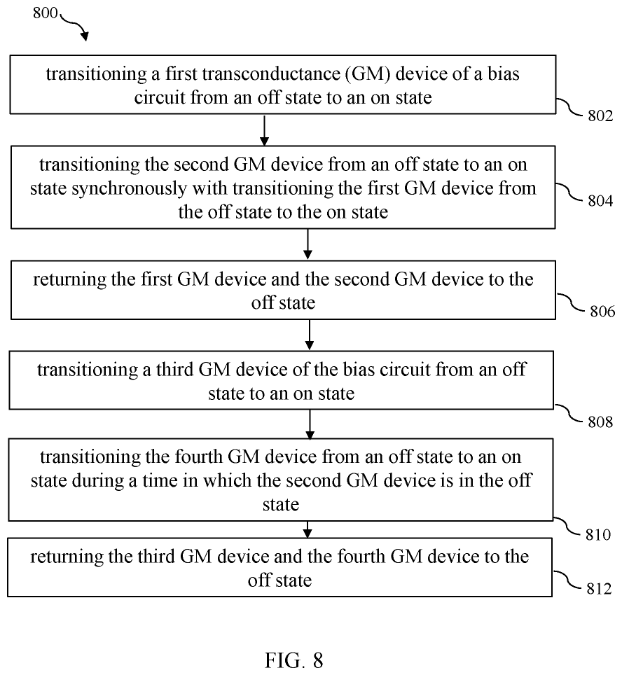

FIG. 8 is a flow diagram illustrating an example process 800 for amplification of a signal, such as an RF signal. The process 800 is described in the form of a set of blocks 802-812 that specify operations that may be performed. However, operations are not necessarily limited to the order shown in FIG. 8 or described herein, for the operations may be implemented in alternative orders or in fully or partially overlapping manners. Operations represented by the illustrated blocks of the process 800 may be performed by an amplifier, such as the one represented at least partially by the schematic diagrams in FIGS. 3 and 7 in conjunction with a bias circuit and under control of a controller, such as data processor/controller 280.

The process 800 may include an input signal being accepted at the input node of the amplifier. For example, the amplifier may accept an input signal relayed from an upstream component, such as a filter, a mixer, a converter unit, or an antenna. The input signal may be applied to the gate of a transistor.

At action 802, the amplifier transitions a first Gm device of a bias circuit from an off state to an on state. For instance, the first Gm device may provide a first bias voltage to a second Gm device of a first amplifier segment. An example includes switchable bias replication device 410 having a Gm device turning on, thereby providing the Vbias Gm devices bias voltage to the gate of transistor 310 (FIGS. 3-4). Turning on the Gm device may include closing a switch.

At action 804, the amplifier transitions the second Gm device from an off state to an on state synchronously with transitioning the first Gm device from the off state to the on state. For instance, transistor 310 may turn on synchronously with switchable bias replication device 410 by virtue of closing switches, such as in the examples described above.

At action 806, the amplifier returns the first Gm device and the second Gm device to the off state. For instance, in the example of FIG. 3, the first gain segment, which includes transistors 310, 320, may be transitioned to an off state so that the gain segment that includes transistors 350, 360 may be used. Returning devices to the off state may include opening switches. Some implementations may turn a device off by opening a series switch and closing a shunt switch to pull the device gate to a certain potential to make sure it is off (ground if NMOS, and VDD if PMOS). Also, when a LNA core Gm device is turned off, the corresponding Gm bias replica may also be turned off and terminated in the same way as the LNA core Gm device. This may ensure that the body is discharged at the same rate and mechanism, so when the Gm devices turn back on they can track each other's threshold voltage.

Actions 802-806 refer to operating a first amplifier segment. Actions 808-812 are offered to show that the method 800 may be scaled to include operation of other amplifier segments. In one example, actions 802-806 describe operation and biasing of the amplifier segment that includes transistors 310, 320. Actions 808-812 may describe operation and biasing of the amplifier segment that includes transistors 350, 360, the amplifier segment 705, or another amplifier segment (not shown)

At action 808, the amplifier transitions a third Gm device of the bias circuit from an off state to an on state. In this example, the third Gm device provides a second bias voltage to a fourth Gm device, where the fourth Gm device may be in a second amplifier segment. An example is shown in FIG. 3 in which the Gm device (transistor 350) is located in a second amplifier segment with cascode 360. In this example, the third Gm device may correspond to the switchable bias replication device 420, which provides the Vbias Gm devices bias voltage to the transistor 350. Turning on the third Gm device may include closing a switch.

At action 810, the amplifier transitions the fourth Gm device from an off state to an on state during a time in which the second Gm devices in the off state. In other words, the separate amplifier segments in FIG. 3 may be used alternately rather than at the same time. An example of transitioning a fourth Gm device from the off state to the on state includes closing switch 363. Turning on the fourth Gm device may include closing a switch.

At action 812, the amplifier returns the third Gm device and the fourth Gm device to the off state. For instance, in the example of FIGS. 3-4, the transistor 350 and the switchable bias replication device 420 may turn off through the action of closing one or more switches.

The disclosure will now be summarized in the following example clauses.
1. An amplifier comprising:
   a first gain segment including: a first transistor, wherein a gate of the first transistor is coupled to an input node of the amplifier, a first terminal of the first transistor is coupled to a power supply or ground, and a second terminal of the first transistor is coupled to an output node of the amplifier through a first cascode transistor;
   a second gain segment including: a second transistor, wherein a gate of the second transistor is coupled to the input node, a first terminal of the second transistor is coupled to the power supply or ground, and a second terminal of the second transistor is coupled to the output node through a second cascode transistor, wherein the first gain segment and the second gain segment are arranged in parallel with respect to the output node;
   a load impedance between the first transistor and a complementary power supply or ground and between the second transistor and the complementary power supply or ground; and
   a bias circuit including: a current source coupled to a first switchable transconductance (Gm) device and a second switchable Gm device, the first switchable Gm device and the second switchable Gm device being arranged in parallel with respect to a voltage bias node coupled to the current source, further wherein the voltage bias node is coupled to the gate of the first transistor and to the gate of the second transistor.
2. The amplifier of clause 1, further comprising:
   a plurality of switches in the first gain segment, the second gain segment, and the bias circuit; and
   a controller configured to control the plurality of switches to synchronize an on and off state of the first transistor and the first switchable Gm device and to synchronize an on state of the second transistor and the second switchable Gm device.
3. The amplifier of any of clauses 1-2, wherein the first switchable Gm device comprises a replica of the first transistor, and wherein the second switchable Gm device comprises a replica of the second transistor.
4. The amplifier of claim 3, wherein the first switchable Gm device and the first transistor are both silicon on insulator (SOI) devices having a same or different length and width and, wherein the second switchable Gm device and the second transistor are both SOI devices having a same or different length and width.
5. The amplifier of claim 3, wherein the first transistor and the second transistor are both silicon on insulator (SOI) devices.
6. The amplifier of any of clauses 1-5, wherein the first gain segment has a lower or higher gain than does the second gain segment.
7. The amplifier of any of clauses 1-6, wherein the bias circuit further comprises a cascode bias device, the cascode bias device being coupled to a gate of the first cascode transistor and to a gate of the second cascode transistor.
8. The amplifier of clause 1, wherein the first switchable Gm device comprises a first diode-connected transistor in series with a first switch, and wherein the second switchable Gm device comprises a second diode-connected transistor in series with a second switch, the first switch and the second switch being coupled to the voltage bias node.
9. The amplifier of clause 7, wherein:
   the first switchable Gm device comprises a first diode-connected transistor coupled to the voltage bias node through a first switch and a third transistor gate-coupled to the first diode-connected transistor, the third transistor being coupled to the cascode bias device through a second switch; and
   the second switchable Gm device comprises a second diode-connected transistor coupled to the voltage bias node through a third switch and a fourth transistor gate-coupled to the second diode-connected transistor, the fourth transistor being coupled to the cascode bias device through a fourth switch.
10. The amplifier of any of clauses 1-10, wherein the amplifier comprises a low noise amplifier (LNA) in a receive path of a transceiver.
11. A method of operating an amplifier, the method comprising:
   transitioning a first transconductance (Gm) device of a bias circuit from an off state to an on state, the first Gm device providing a first bias voltage to a second Gm device of a first amplifier segment; and
   transitioning the second Gm device from an off state to an on state synchronously with transitioning the first Gm device from the off state to the on state.
12. The method of clause 11, further comprising:
   returning the first Gm device and the second Gm device to the off state;
   transitioning a third Gm device of the bias circuit from an off state to an on state, the third Gm device providing a second bias voltage to a fourth Gm device of a second amplifier segment;
   transitioning the fourth Gm device from an off state to an on state during a time in which the second Gm device is in the off state; and
   returning the third Gm device and the fourth Gm device to the off state.
13. The method of clause 12, wherein transitioning the second Gm device from the off state to the on state comprises:
   closing a switch that couples the first bias voltage to the second Gm device based on a control signal from a controller of a transceiver; and
   turning on a cascode that is disposed in series with the second Gm device using the bias circuit.
14. The method of clause 12, wherein transitioning the fourth Gm device from the off state to the on state comprises:
   closing a switch that couples the second bias voltage to the fourth Gm device based on a control signal from a controller of a transceiver; and
   turning on a cascode that is disposed in series with the fourth Gm device using the bias circuit.
15. The method of clause 12, wherein returning the second Gm device to the off state comprises:
   opening a switch that couples the first bias voltage to the second Gm device based on a control signal from a controller of a transceiver; and
   turning off a cascode that is disposed in series with the second Gm device sing the bias circuit.
16. The method of clause 12, wherein returning the fourth Gm device to the off state comprises:
   opening a switch that couples the second bias voltage to the fourth Gm device based on a control signal from a controller of a transceiver; and
   turning off a cascode that is disposed in series with the fourth Gm device using the bias circuit.
17. The method of clause 12, wherein the second amplifier segment has a lower gain than does the first amplifier segment.
18. The method of any of clauses 12-17, wherein the first amplifier segment and the second amplifier segment operate alternatively.
19. The method of any of clauses 11-17, wherein the first Gm device and the second Gm device are both silicon on insulator (SOI) devices.
20. The method of any of clauses 11-17, wherein the first Gm device comprises a replica of the second Gm device.
21. The method of any of clauses 11-17, wherein the first amplifier segment is implemented in a low noise amplifier (LNA) of a transceiver, the method further comprising:
   amplifying a received RF signal by the first amplifier segment as the first bias voltage is applied to the second Gm device.
22. A method of operating a low noise amplifier (LNA) to amplify a radio frequency (RF) signal, the method comprising:
   synchronizing turning on a first Gm device of a bias circuit with turning on a second Gm device of a first segment of the LNA, wherein the first Gm device provides a first bias voltage to the second Gm device; and
   synchronizing turning on a third Gm device of the bias circuit with turning on a fourth Gm device of a second segment of the LNA, wherein the third Gm device provides a second bias voltage to the fourth Gm device.
23. The method of clause 22, wherein the first Gm device is coupled to a current source through a first switch, and wherein the third Gm device is coupled to the current source through a second switch,
   wherein turning on the first Gm device comprises closing the first switch; and
   wherein turning on the third Gm device comprises closing the second switch, wherein operation of the first switch and the second switch are timed to alternate an on state between the first Gm device and the third Gm device.
24. The method of any of clauses 22-23, wherein the second Gm device is coupled to a power or ground through a source or drain of a first cascode, and wherein the fourth Gm device is coupled to the power or ground through a source or drain of a second cascode,
   wherein turning on the second Gm device comprises turning on the first cascode; and
   wherein turning on the fourth Gm device comprises turning on the second cascode, wherein operation of the first cascode and the second cascode are timed to alternate an on state between the second Gm device and the fourth Gm device.
25. The method of any of clauses 22-24, wherein the first Gm device, the second Gm device, the third Gm device, and the fourth Gm device are all silicon on insulator (SOI) devices.
26. A low noise amplifier (LNA) comprising:
   a radio frequency (RF) input;
   an RF output;
   a first gain segment including: a first transistor, wherein a gate of the first transistor is coupled to the RF input, a first terminal of the first transistor is coupled to a power supply or ground, and a second terminal of the first transistor is coupled to the RF output;
   a second gain segment including: a second transistor, wherein a gate of the second transistor is coupled to the RF input, a first terminal of the second transistor is coupled to the power supply or ground, and a second terminal of the second transistor is coupled to the RF output, wherein the first gain segment and the second gain segment are arranged in parallel with respect to the RF output;
   a bias circuit including: a current source coupled to a first transconductance (Gm) device and a second Gm device, the first Gm device and the second Gm device being arranged in parallel with respect to a voltage bias node coupled to the current source, further wherein the voltage bias node is coupled to the gate of the first transistor and to the gate of the second transistor;
   means for synchronizing a transition of the first transistor to an on state with a transition of the first Gm device to an on state; and
   means for synchronizing a transition of the second transistor to an on state with a transition of the second Gm device to an on state.
27. The LNA of clause 26, wherein the first transistor is coupled to the power supply or ground by a first cascode, the LNA further comprising:
   means for synchronizing the transition of the first transistor to the on state with the transition of the first cascode to the on state.
28. The LNA of clause 27, wherein the second transistor is coupled to the power supply or ground by a second cascode, the LNA further comprising:
   means for synchronizing the transition of the second transistor to the on state with the transition of the second cascode to an on state.
29. The LNA of clause 28, wherein the bias circuit further comprises:
   means for biasing the first cascode and the second cascode.
30. The LNA of clause 26, wherein the first transistor, the second transistor, the first Gm device, and the second Gm device are all silicon on insulator (SOI) devices.

Those of skill in the art would understand that information and signals may be represented using any of a variety of different technologies and techniques. For example, data, instructions, commands, information, signals, bits, symbols, and chips that may be referenced throughout the above description may be represented by voltages, currents, electromagnetic waves, magnetic fields or particles, optical fields or particles, or any combination thereof.

Those of skill in the art would further appreciate that the various illustrative logical blocks, modules, circuits, and algorithm steps described in connection with the exemplary aspects disclosed herein may be implemented as electronic hardware, computer software, or combinations of both. To clearly illustrate this interchangeability of hardware and software, various illustrative components, blocks, modules, circuits, and steps have been described above generally in terms of their functionality. Whether such functionality is implemented as hardware or software depends upon the particular application and design constraints imposed on the overall system. Skilled artisans may implement the described functionality in varying ways for each particular application, but such implementation decisions should not be interpreted as causing a departure from the scope of the exemplary aspects of the disclosure.

The various illustrative logical blocks, modules, and circuits described in connection with the exemplary aspects disclosed herein may be implemented or performed with a general purpose processor, a Digital Signal Processor (DSP), an Application Specific Integrated Circuit (ASIC), a Field Programmable Gate Array (FPGA) or other programmable logic device, discrete gate or transistor logic, discrete hardware components, or any combination thereof designed to perform the functions described herein. A general purpose processor may be a microprocessor, but in the alternative, the processor may be any conventional processor, controller, microcontroller, or state machine. A processor may also be implemented as a combination of computing devices, e.g., a combination of a DSP and a microprocessor, a plurality of microprocessors, one or more microprocessors in conjunction with a DSP core, or any other such configuration.

The steps of a method or algorithm described in connection with the exemplary aspects disclosed herein may be embodied directly in hardware, in a software module executed by a processor, or in a combination of the two. A software module may reside in Random Access Memory (RAM), flash memory, Read Only Memory (ROM), Electrically Programmable ROM (EPROM), Electrically Erasable Programmable ROM (EEPROM), registers, hard disk, a removable disk, a CD-ROM, or any other form of storage medium known in the art. An exemplary storage medium is coupled to the processor such that the processor can read information from, and write information to, the storage medium. In the alternative, the storage medium may be integral to the processor. The processor and the storage medium may reside in an ASIC. The ASIC may reside in a user terminal. In the alternative, the processor and the storage medium may reside as discrete components in a user terminal.

In one or more exemplary aspects, the functions described may be implemented in hardware, software, firmware, or any combination thereof. If implemented in software, the functions may be stored on or transmitted over as one or more instructions or code on a computer-readable medium. Computer-readable media includes both computer storage media and communication media including any medium that facilitates transfer of a computer program from one place to another. A storage media may be any available media that can be accessed by a computer. By way of example, and not limitation, such computer-readable media can comprise RAM, ROM, EEPROM, CD-ROM or other optical disk storage, magnetic disk storage or other magnetic storage devices, or any other medium that can be used to carry or store desired program code in the form of instructions or data structures and that can be accessed by a computer. Also, any connection is properly termed a computer-readable medium. For example, if the software is transmitted from a website, server, or other remote source using a coaxial cable, fiber optic cable, twisted pair, digital subscriber line (DSL), or wireless technologies such as infrared, radio, and microwave, then the coaxial cable, fiber optic cable, twisted pair, DSL, or wireless technologies such as infrared, radio, and microwave are included in the definition of medium. Disk and disc, as used herein, includes compact disc (CD), laser disc, optical disc, digital versatile disc (DVD), floppy disk and Blu-Ray disc where disks usually reproduce data magnetically, while discs reproduce data optically with lasers. Combinations of the above should also be included within the scope of computer-readable media.

The previous description of the disclosed exemplary aspects is provided to enable any person skilled in the art to make or use the disclosed embodiments. Various modifications to these exemplary aspects will be readily apparent to those skilled in the art, and the generic principles defined herein may be applied to other exemplary aspects without departing from the spirit or scope of the disclosed embodiments. Thus, the present disclosure is not intended to be limited to the exemplary aspects shown herein but is to be accorded the widest scope consistent with the principles and novel features disclosed herein.

What is claimed is:

1. An amplifier comprising:
a first gain segment including: a first transistor, wherein a gate of the first transistor is coupled to an input node of the amplifier, a first terminal of the first transistor is coupled to a power supply or ground, and a second terminal of the first transistor is coupled to an output node of the amplifier through a first cascode transistor;
a second gain segment including: a second transistor, wherein a gate of the second transistor is coupled to the input node, a first terminal of the second transistor is coupled to the power supply or ground, and a second terminal of the second transistor is coupled to the output node through a second cascode transistor, wherein the first gain segment and the second gain segment are arranged in parallel with respect to the output node;
a load impedance between the first transistor and a complementary power supply or ground and between the second transistor and the complementary power supply or ground; and
a bias circuit including: a current source coupled to a first switchable transconductance (Gm) device and a second switchable Gm device, the first switchable Gm device and the second switchable Gm device being arranged in parallel with respect to a voltage bias node coupled to the current source, further wherein the voltage bias node is coupled to the gate of the first transistor and to the gate of the second transistor.

2. The amplifier of claim 1, further comprising:
a plurality of switches in the first gain segment, the second gain segment, and the bias circuit; and
a controller configured to control the plurality of switches to synchronize an on state and an off state of the first transistor and the first switchable Gm device and to synchronize an on state of the second transistor and the second switchable Gm device.

3. The amplifier of claim 1, wherein the first switchable Gm device comprises a replica of the first transistor, and wherein the second switchable Gm device comprises a replica of the second transistor.

4. The amplifier of claim 3, wherein the first switchable Gm device and the first transistor are both silicon on insulator (SOI) devices having a same or different length and width and, wherein the second switchable Gm device and the second transistor are both SOI devices having a same or different length and width.

5. The amplifier of claim 3, wherein the first transistor and the second transistor are both silicon on insulator (SOI) devices.

6. The amplifier of claim 1, wherein the first gain segment has a lower or higher gain than does the second gain segment.

7. The amplifier of claim 1, wherein the first switchable Gm device comprises a first diode-connected transistor in series with a first switch, and wherein the second switchable Gm device comprises a second diode-connected transistor in series with a second switch, the first switch and the second switch being coupled to the voltage bias node.

8. The amplifier of claim 1, wherein the bias circuit further comprises a cascode bias device, the cascode bias device being coupled to a gate of the first cascode transistor and to a gate of the second cascode transistor.

9. The amplifier of claim 8, wherein:
the first switchable Gm device comprises a first diode-connected transistor coupled to the voltage bias node through a first switch and a third transistor gate-coupled to the first diode-connected transistor, the third transistor being coupled to the cascode bias device through a second switch; and
the second switchable Gm device comprises a second diode-connected transistor coupled to the voltage bias node through a third switch and a fourth transistor gate-coupled to the second diode-connected transistor, the fourth transistor being coupled to the cascode bias device through a fourth switch.

10. The amplifier of claim 1, wherein the amplifier comprises a low noise amplifier (LNA) in a receive path of a transceiver.

11. A method of operating an amplifier, the method comprising:
transitioning a first transconductance (Gm) device of a bias circuit from an off state to an on state, the first Gm device providing a first bias voltage to a second Gm device of a first amplifier segment; and
transitioning the second Gm device from an off state to an on state synchronously with transitioning the first Gm device from the off state to the on state.

12. The method of claim 11, further comprising:
returning the first Gm device and the second Gm device to the off state;
transitioning a third Gm device of the bias circuit from an off state to an on state, the third Gm device providing a second bias voltage to a fourth Gm device of a second amplifier segment;
transitioning the fourth Gm device from an off state to an on state during a time in which the second Gm device is in the off state; and
returning the third Gm device and the fourth Gm device to the off state.

13. The method of claim 12, wherein transitioning the second Gm device from the off state to the on state comprises:
closing a switch that couples the first bias voltage to the second Gm device based on a control signal from a controller of a transceiver; and
turning on a cascode that is disposed in series with the second Gm device using the bias circuit.

14. The method of claim 12, wherein transitioning the fourth Gm device from the off state to the on state comprises:
closing a switch that couples the second bias voltage to the fourth Gm device based on a control signal from a controller of a transceiver; and
turning on a cascode that is disposed in series with the fourth Gm device using the bias circuit.

15. The method of claim 12, wherein returning the second Gm device to the off state comprises:
opening a switch that couples the first bias voltage to the second Gm device based on a control signal from a controller of a transceiver; and
turning off a cascode that is disposed in series with the second Gm device sing the bias circuit.

16. The method of claim 12, wherein returning the fourth Gm device to the off state comprises:
opening a switch that couples the second bias voltage to the fourth Gm device based on a control signal from a controller of a transceiver; and
turning off a cascode that is disposed in series with the fourth Gm device using the bias circuit.

17. The method of claim 12, wherein the second amplifier segment has a lower gain than does the first amplifier segment.

18. The method of claim 17, wherein the first amplifier segment and the second amplifier segment operate alternatively.

19. The method of claim 11, wherein the first Gm device and the second Gm device are both silicon on insulator (SOI) devices.

20. The method of claim 11, wherein the first Gm device comprises a replica of the second Gm device.

21. The method of claim 11, wherein the first amplifier segment is implemented in a low noise amplifier (LNA) of a transceiver, the method further comprising:
amplifying a received RF signal by the first amplifier segment as the first bias voltage is applied to the second Gm device.

22. A method of operating a low noise amplifier (LNA) to amplify a radio frequency (RF) signal, the method comprising:
synchronizing turning on a first Gm device of a bias circuit with turning on a second Gm device of a first segment of the LNA, wherein the first Gm device provides a first bias voltage to the second Gm device; and
synchronizing turning on a third Gm device of the bias circuit with turning on a fourth Gm device of a second segment of the LNA, wherein the third Gm device provides a second bias voltage to the fourth Gm device.

23. The method of claim 22, wherein the first Gm device is coupled to a current source through a first switch, and wherein the third Gm device is coupled to the current source through a second switch,
wherein turning on the first Gm device comprises closing the first switch; and
wherein turning on the third Gm device comprises closing the second switch, wherein operation of the first switch and the second switch are timed to alternate an on state between the first Gm device and the third Gm device.

24. The method of claim 22, wherein the second Gm device is coupled to a power or ground through a source or drain of a first cascode, and wherein the fourth Gm device is coupled to the power or ground through a source or drain of a second cascode,
wherein turning on the second Gm device comprises turning on the first cascode; and
wherein turning on the fourth Gm device comprises turning on the second cascode, wherein operation of the first cascode and the second cascode are timed to alternate an on state between the second Gm device and the fourth Gm device.

25. The method of claim 22, wherein the first Gm device, the second Gm device, the third Gm device, and the fourth Gm device are all silicon on insulator (SOI) devices.

26. A low noise amplifier (LNA) comprising:
a radio frequency (RF) input;
an RF output;
a first gain segment including: a first transistor, wherein a gate of the first transistor is coupled to the RF input, a first terminal of the first transistor is coupled to a power supply or ground, and a second terminal of the first transistor is coupled to the RF output;
a second gain segment including: a second transistor, wherein a gate of the second transistor is coupled to the RF input, a first terminal of the second transistor is coupled to the power supply or ground, and a second terminal of the second transistor is coupled to the RF output, wherein the first gain segment and the second gain segment are arranged in parallel with respect to the RF output;
a bias circuit including: a current source coupled to a first transconductance (Gm) device and a second Gm device, the first Gm device and the second Gm device being arranged in parallel with respect to a voltage bias node coupled to the current source, further wherein the voltage bias node is coupled to the gate of the first transistor and to the gate of the second transistor;
means for synchronizing a transition of the first transistor to an on state with a transition of the first Gm device to an on state; and
means for synchronizing a transition of the second transistor to an on state with a transition of the second Gm device to an on state.

27. The LNA of claim 26, wherein the first transistor is coupled to the power supply or ground by a first cascode, the LNA further comprising:
means for synchronizing the transition of the first transistor to the on state with the transition of the first cascode to the on state.

28. The LNA of claim 27, wherein the second transistor is coupled to the power supply or ground by a second cascode, the LNA further comprising:
means for synchronizing the transition of the second transistor to the on state with the transition of the second cascode to the on state.

29. The LNA of claim 28, wherein the bias circuit further comprises:
means for biasing the first cascode and the second cascode.

30. The LNA of claim 26, wherein the first transistor, the second transistor, the first Gm device, and the second Gm device are all silicon on insulator (SOI) devices.
